(19) United States
(12) Patent Application Publication
(10) Pub. No.: US 2026/0031593 A1
(43) Pub. Date: Jan. 29, 2026

(54) LASER ARRAY WITH EMITTER ISOLATION

(71) Applicant: DAYLIGHT SOLUTIONS, INC., San Diego, CA (US)

(72) Inventors: Kevin Oresick, Nivelles (BE); Matt Dwyer, Madison, WI (US); Thomas L. Earles, Madison, WI (US)

(21) Appl. No.: 18/994,348

(22) PCT Filed: Jun. 27, 2023
(86) PCT No.: PCT/US2023/069156

§ 371 Date: Jan. 14, 2025

Related U.S. Application Data
(60) Provisional application No. 63/389,682, filed on Jul. 15, 2022.

(51) Int. Cl. H01S 5/042; H01S 5/00; H01S 5/34; H01S 5/40

(52) U.S. Cl. CPC H01S 5/042; H01S 5/0014; H01S 5/3402; H01S 5/4025

(57) ABSTRACT

A laser assembly (10) includes a substrate (22); a plurality of spaced apart, lasers (20) grown on the substrate (22); and an electrical connector assembly (14). The lasers (20) are individually tested to identify if the tested lasers (20) are a good laser (20a) or a bad laser (20b). The electrical connector assembly (14) is adapted to electrically connect a supply source (16) of electrical power to the identified good lasers (20a), while not electrically connecting the identified bad lasers (20b) to the supply source (16). Thus, the identified bad lasers (20B) are electrically isolated from the supply source (16).

### RELATED APPLICATION

This application claims priority on U.S. Provisional Application No: 63/389,682 filed on Jul. 15, 2022, and entitled “LASER ARRAY WITH EMITTER ISOLATION”. As far as permitted, the contents of U.S. Provisional Application No: 63/389,682 are incorporated herein.

### BACKGROUND

Multiple lasers can be grown on a semiconductor wafer, and the wafer can be cut into a plurality of laser arrays, with each laser array having multiple lasers. Depending upon the type of laser, it can be very difficult to accurately grow each of the lasers on the wafer. This greatly reduces the yield of usable laser arrays from the semiconductor wafer. As result thereof, there is a need to increase the yield of usable laser arrays from the semiconductor wafer.

### SUMMARY

A laser assembly as provided herein includes a substrate; a laser array including a plurality of spaced apart, lasers grown on the substrate; and an electrical connector assembly. In one implementation, at least two of the lasers are individually tested to identify if the tested lasers are a good laser or a bad laser. Further, the electrical connector assembly is adapted to electrically connect a supply source of electrical power to the identified good lasers while electrically isolating the identified bad lasers.

Stated in another fashion, the lasers of the laser array can be analyzed and individually tested to individually identify the “good lasers”, and the “bad lasers”. Subsequently, the laser array and/or the electrical connector assembly can be modified and/or adjusted to electrically isolate the identified lasers. Thus, the bad lasers are identified and isolated. As a result thereof, the bad lasers will not heat or short out the laser array, and laser array will be usable and more reliable. This will increase the yield of usable laser arrays.

In one implementation, the electrical connector assembly includes a non-conducting layer that is positioned in the path of at least one of the identified bad lasers. In a specific implementation, each identified bad laser can include an electrical pad, and the non-conducting layer can be a dielectric that is positioned over the electrical pad.

The non-conducting layer can be selected from a group that includes silicon dioxide (SiO2), aluminum oxide (Al2O3), silicon nitride (Si3N4), or titanium oxide (TiO).

The dielectric can be deposited with a shadow mask using a line of sight deposition technique.

In certain implementations, at least one of the lasers is a quantum cascade gain medium.

In one implementation, each of plurality of the lasers is individually tested to identify if the tested lasers are a good laser or a bad laser.

Further, the electrical connector assembly can be adapted to electrically connect the supply source to all of the identified good lasers, while electrically isolating all of the identified bad lasers.

In another implementation, the laser assembly again includes a substrate; a plurality of spaced apart, lasers grown on the substrate; and an electrical connector assembly. In this implementation, at least two of the lasers are individually tested to identify if the tested laser is a good laser or a bad laser. Moreover, at least a portion of one of the bad lasers is removed after being identified as a bad laser. Further, the electrical connector assembly is adapted to electrically connect the supply source to the identified good lasers while electrically isolating the identified bad lasers.

In one implementation, the removal is achieved by ablation using a laser or ion beam. Alternatively, the removal can be achieved through chemical etching.

Moreover, the laser assembly can additionally include a protective layer positioned over the identified good lasers to protect the good lasers during the removal of the portion of one of the bad lasers.

In certain implementations, each of plurality of the lasers are individually tested to identify if the tested lasers are a good laser or a bad laser. In this design, at least a portion of each of the bad lasers is removed after being identified as a bad laser.

In another implementation, a method for making a laser assembly powered by a supply source includes: providing a substrate including a laser array grown on the substrate, the laser array having a plurality of spaced apart, lasers; individually testing at least two of the lasers to identify if the tested lasers are a good laser or a bad laser; and electrically connecting the supply source to the identified good laser while not electrically connecting the identified bad laser with an electrical connector assembly.

In still another implementation, a method for making a laser assembly powered by a supply source includes: providing a substrate including a laser array grown on the substrate, the laser array having a plurality of spaced apart, lasers; individually testing at least two of the lasers to identify if the tested lasers are a good laser or a bad laser; and electrically connecting the supply source to the identified good laser while not electrically connecting the identified bad laser with an electrical connector assembly.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a simplified schematic, side illustration of a laser assembly, including a laser array;

FIG. 2 is a simplified top illustration of a laser array;

FIG. 3 is a graph that illustrates the optical power of a plurality of individual lasers in a laser array;

FIG. 4 is a simplified side illustration of a portion of a laser array;

FIG. 5 is a simplified side illustration of the laser array of FIG. 4 electrically connected to an electrical connector assembly;

FIG. 6 is a simplified side illustration of another portion of the laser array:

FIG. 7 is a simplified side illustration of another laser array electrically connected to an electrical connector assembly; and

FIG. 8 is a simplified side illustration another implementation of the laser array electrically connected to an electrical connector assembly.

### DESCRIPTION

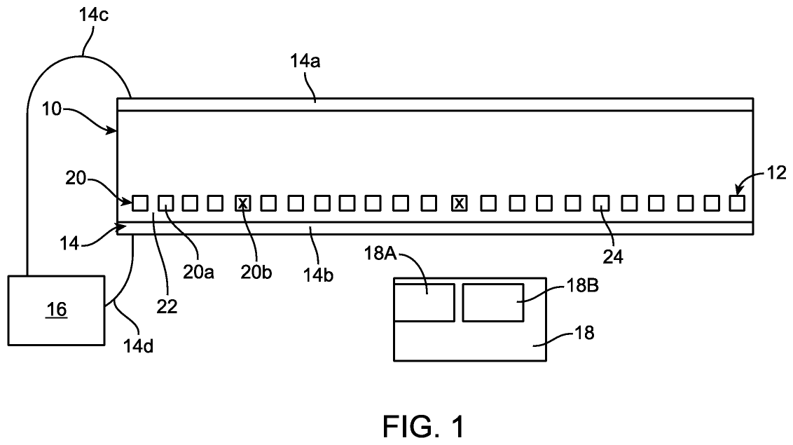

FIG. 1 is a simplified schematic, side illustration of (i) a laser assembly 10 including a laser array 12 and an electrical connector assembly 14, (ii) a supply source 16 (illustrated as a box), and (iii) a control system 18 (illustrated as a box) that controls the operation of the laser assembly 10. In this implementation, the laser array 12 includes a plurality of spaced apart, individual lasers 20 (each illustrated as a box) that have been grown on a substrate 22.

For each of the embodiments disclosed herein, the number of lasers 20 in the laser array 12 can be varied to suit the output requirements of the laser assembly 10. In the non-exclusive implementation of FIG. 1, the laser array 12 includes twenty-three spaced apart lasers 20. Alternatively, the laser array 12 can be designed to have more than or fewer than twenty-three spaced apart lasers 20. As alternative, non-exclusive implementations, the laser array 12 can be designed to include at least 5, 8, 10, 15, 20, 25, 30, 40, 50, 60, 70, 80, 90, 100, 120, 150, or 200 individual lasers 20 on a common substrate 22.

Generally, for a given laser array 12 design, the potential power output of the laser array 12 will increase as the number of lasers 20 in the laser array 12 is increased. Thus, the number of lasers 20 can be adjusted to fit the desired application and the desired power output of the laser assembly 10.

The design of each lasers 20 can also be varied to achieve the output requirements (e.g., wavelength and optical power) of the laser assembly 10. As alternative, non-exclusive examples, one or more (e.g., all) of the lasers 20 can be a quantum cascade gain medium, a quantum well gain medium, or another type of gain medium.

As a non-exclusive example, each of the lasers 20 can be designed to generate between approximately one to two watts. However, other values are possible. As alternative examples, each of the lasers 20 can be designed to generate at least approximately one half, one, two, or three watts.

It should be noted that each of the lasers 20 can alternatively be referred to as an emitter or a gain medium. Further, any of the lasers 20 can be referred to as a first, second, third, fourth, etc., laser.

In FIG. 1, an outlet facet 24 of each laser 20 is shown, and each functioning laser 20 will emit light from the output facet 24 when sufficiently powered by the supply source 16. Alternatively, one or more of the lasers 20 can be designed to emit from two facets.

The type of substrate 22 can be varied to suit the design of the lasers 20. As alternative, non-exclusive examples, the substrate 22 can be made of indium phosphide (“InP”), silicon, or other suitable material.

In certain designs, the lasers 20 are grown on a common semiconductor wafer (not shown). Subsequently, the wafer and lasers 20 are cut into a plurality of bars, with each bar defining one laser array 12. The number of bars in a given semiconductor wafer will depend on a number of factors, including (but not limited to) the desired number of lasers 20 in the laser array 12 and/or the size of the semiconductor wafer. As non-exclusive examples, the wafer can be cut into at least 2, 10, 20, 30, 50, 100, 1000 or more laser arrays 12.

As provided herein, depending upon the type of laser 20, it is often very difficult to accurately grow each of the lasers 20 on the wafer. As result thereof, one or more of the lasers 20 can be weak or dead (collectively referred to as “bad lasers”). Each weak laser 20 can generate significant amounts of heat when powered by the supply source 16. This can adversely influence the laser array 12, and the weak lasers 20 are more likely to subsequently fail. The dead lasers 20 can short out the entire laser array 12. Thus, the weak and dead lasers 20 can greatly reduce the yield of the usable laser arrays 12 from the semiconductor wafer.

As an overview, as provided herein, the lasers 20 of the laser array 12 can be analyzed and individually tested to individually identity the “good lasers” 20a, and the “bad lasers” 20b (represented with an “x”) in the laser array 12. Subsequently, the laser array 12 and/or the electrical connector assembly 14 are modified and/or adjusted to electrically isolate the bad lasers 20b. Thus, the bad lasers 20b are identified and isolated. As a result thereof, the bad lasers 20b will not heat or short out the laser array 12, and laser array 12 will be usable. This will increase the yield of usable laser arrays 12 from the wafer.

Stated in a different fashion, the present invention teaches that the bad lasers 20b can be electrically isolated, and the laser array 12 is still usable as long as the laser array 12 includes a sufficient number of good lasers 20a. For example, in a simplified example, the optical power for the desired application can be generated by twenty lasers 20 in the laser array 12. In FIG. 1, the lasers 20 were individually tested, and the laser array 12 includes twenty-one “good lasers” 20a, and two “bad lasers” 20b. In this example, the laser array 12 is acceptable because there are twenty or more good lasers 20a. Stated differently, in this example, the laser array 12 is acceptable because there are three or less bad lasers 20b.

The number of good lasers 20a and bad lasers 20b in a given laser array 12 will vary depending on manufacturing. As alternative, non-exclusive examples, the grown laser array 12 can include (i) at least 5, 8, 10, 15, 20, 25, 30, 40, 50, 60, 70, 80, 90, 100, 120, 150, or 200 individual, good lasers 20a; and/or (ii) at least 1, 2, 3, 4, 5, 6, 7, 8, 9, or 10 bad lasers 20b. It should be noted that it doesn't matter how many bad lasers there are, and the any number of bad lasers 20b can be isolated. Generally, speaking, as the number of total lasers 20 is increased, the number of bad lasers 20b will also increase. As a non-exclusive, extreme example, the laser array 12 can include two hundred good lasers 20a, and two hundred bad lasers 20b.

As provided herein, for obtaining high reliability and yields for laser arrays 12, testing and processing can be used to identify and isolate bad laser(s) 20b. This eliminates the bad laser(s) 20b from being a point of failure for the laser array 12. This is particularly valuable for high emitter count quantum cascade arrays where buried heterostructure processing makes it difficult to obtain high yields.

In summary, the present design improves the reliability of the laser arrays 12, and yields for laser arrays 12 by identifying and isolating bad emitters 20b.

The electrical connector assembly 14 electrically connects the laser array 12 to the supply source 16. In FIG. 1, the electrical connector assembly 14 is represented by (i) an upper, first conductor plate 14a that is electrically connected to each of the good lasers 20a; (ii) a lower, second conductor plate 14b that is electrically connected to each of the good lasers 20a; (iii) a first connector 14c that electrically connects the first conductor plate 14a to the supply source 16; and (iv) a second connector 14d that electrically connects the second conductor plate 14b to the supply source 16. Alternatively, or additionally, the electrical connector assembly 14 can include one or more electrical leads and/or connectors. In one, non-exclusive design, the electrical connector assembly 14 connects the good lasers 20a in parallel to the supply source 16 so that the good lasers 20a emit light substantially concurrently. Alternatively, for example, the electrical connector assembly 14 can electrically connect the good lasers 20a to the supply source 16 in series.

The supply source 16 directs power, e.g., current and/or voltage, to the laser array 12 via the electrical connector assembly 14. For example, the supply source 16 can be pulsed or constant.

The control system 18 controls the operation of the supply source 16 and the power output of the laser array 12. The control system 18 can include one or more processors 18A and/or electronic data storage devices 18B. It should be noted that the control system 18 is illustrated in FIG. 1 as a single, central processing system. Alternatively, the control system 18 can be a distributed processing system.

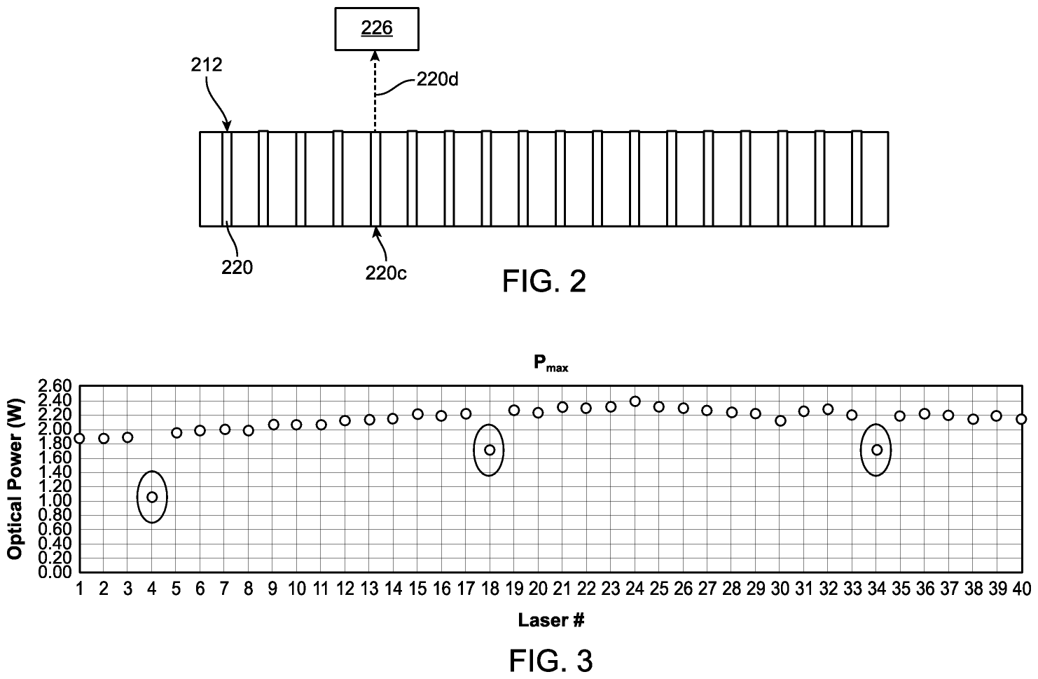

FIG. 2 is a simplified top illustration of another implementation of a laser array 212 including eighteen, spaced apart lasers 220. In one, non-exclusive embodiment, each laser 220 of the laser array 212 is individually tested after the laser arrays 212 are cut from the wafer, and prior to connecting to the electrical connector assembly 14 (illustrated in FIG. 1).

In FIG. 2, one of the lasers 220 is highlighted and labeled 220c because power is being directed to this activated laser 220c, and it is being individually tested. In FIG. 2, dashed arrow 220d represents the output beam (e.g., laser beam) that is generated by the activated laser 220c.

Further, FIG. 2, illustrates a detector assembly 226 (illustrated as a box) that is used to test the individual lasers 220. For example, the detector assembly 226 can be a sensor that measures the power output of the generated output beam 220d to test the individual activated laser 220c.

In one embodiment, the lasers 220 are sequentially, individually powered, and individually tested to measure the respective power output of each laser 220. Subsequently, the optical power output of each laser 220 can be used to evaluate and identify the good lasers 20a (see FIG. 1) and the bad lasers 20b (see FIG. 1). In this design, prior to packaging, each emitter 220 is individually probed and tested for electro-optical performance.

Alternatively, the detector assembly 226 can be designed so that multiple (e.g., all) of the lasers 220 can be simultaneously powered, and the optical power output of powered lasers 220 can be individually measured to individually determine the corresponding electro-optical performance, and identify the powered lasers 220 as either a good laser 20a or a bad laser 20b.

It should be noted that other methods other than optical power output can be used to identify the good lasers 20a, and bad lasers 20b. As non-exclusive examples, resistance measurements, or localized temperature spikes of the individual lasers can be utilized to identify the good lasers 20a, and bad lasers 20b.

FIG. 3 is a graph that illustrates the optical power output of a plurality of activated (tested) lasers in the laser array. In this example, the laser array included forty, spaced apart lasers. As FIG. 3 illustrates, in this non-exclusive example, laser number 4, laser number 18, and laser number 34 are generating significantly less optical power than the other lasers. In this example, laser number 4, 18, and 34 can be labeled bad lasers while the remaining thirty-seven lasers can be labeled as good lasers. As provided herein, these bad lasers are electrically isolated (not electrically connected to the supply source 16 (illustrated in FIG. 1)) because these bad lasers are prone to excess heating and early failure.

In this design, (i) a bad laser has relatively low optical power output, and (ii) a good laser has relatively high optical power output. It should be noted that difference between the optical power output for a good laser and a bad laser can be varied. As non-exclusive examples, a laser can be labeled and identified as a “bad laser” if its optical output power is less than 90, 80, 70, 60, 50, 40, 30, 20, or 10 percent of the designed optical output power of the laser.

It should also be noted that the term “bad laser” includes both a weak laser (e.g., having relatively low optical output power) when powered by the supply source 16, and a dead laser (e.g., generates no optical output power) when powered by the supply source 16.

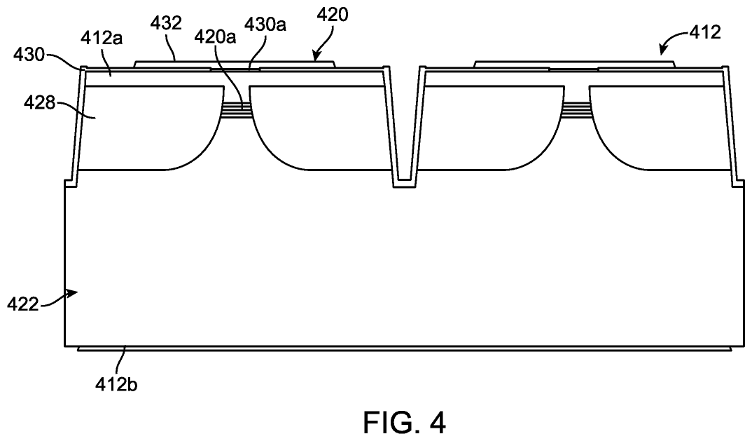

FIG. 4 is a simplified, more detailed, side illustration of a small laser array 412. In this simplified example, the laser array includes the substrate 422 and only two individual lasers 420. It should be noted that that the laser array 412 will typically be designed and built to include more than two individual lasers 412 on the substrate 422, as described above. These additional lasers (not shown) can be similar to the illustrated lasers 420.

During the growth process, multiple layers are sequentially grown on the substrate 422. Subsequently, a portion of this material is removed and filled with an insulating regrowth 428 to form an individual gain region 420a for each laser 420. It should be noted that the laser array 412 of FIG. 4 has an epi side 412a and an opposed base side 412b.

Further, as illustrated in FIG. 4, the laser array 412 can include an insulating layer 430 that covers and separates each laser 420, and a separate electrical contact pad 432 for each of the lasers 420. In this design, (i) the insulating layer 430 includes a separate layer aperture 430a positioned over the gain region 420a of each laser 420, (ii) each electrical contact pad 432 is positioned on the insulating layer 430, and (iii) each electrical contact pad 432 is electrically connected through a corresponding layer aperture 430a to a corresponding gain region 420a.

In this non-exclusive example, the two lasers 420 were tested and determined to be good lasers.

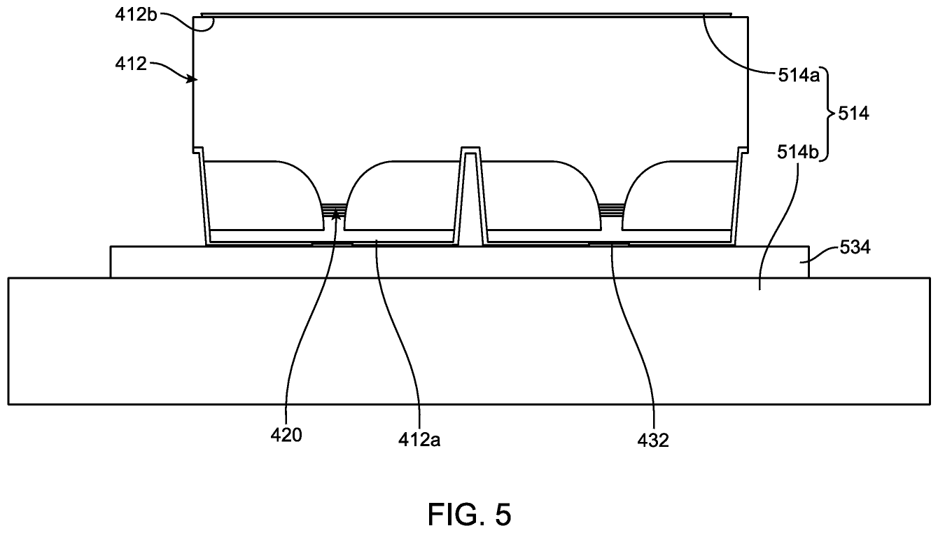

FIG. 5 is a simplified side illustration of the laser array 412 of FIG. 4 electrically connected to the electrical connector assembly 514 with the epi side 412a down.

In the non-exclusive implementation of FIG. 5, the electrical connector assembly 514 includes the first conductor plate 514a that is electrically connected to the base side 412b of the laser array 412, and the second conductor plate 514b that is electrically connected (e.g., by solder 534) to the electrical contact pads 432. In this design, the conductor plates 514a, 514b are electrically connected to the supply source 16 (illustrated in FIG. 1).

As provided above, in this example, the two lasers 420 illustrated were tested and determined to be good lasers. Thus, with the laser array 412 illustrated in FIG. 5, the two lasers 420 are electrically connected to the supply source 16 via the electrical connector assembly 414. With this design, power from the supply source 16 can drive both lasers 420.

Additionally, in the design of FIG. 5, the second conductor plate 514b can additionally and optionally function as a heatsink to remove heat from the laser array 412.

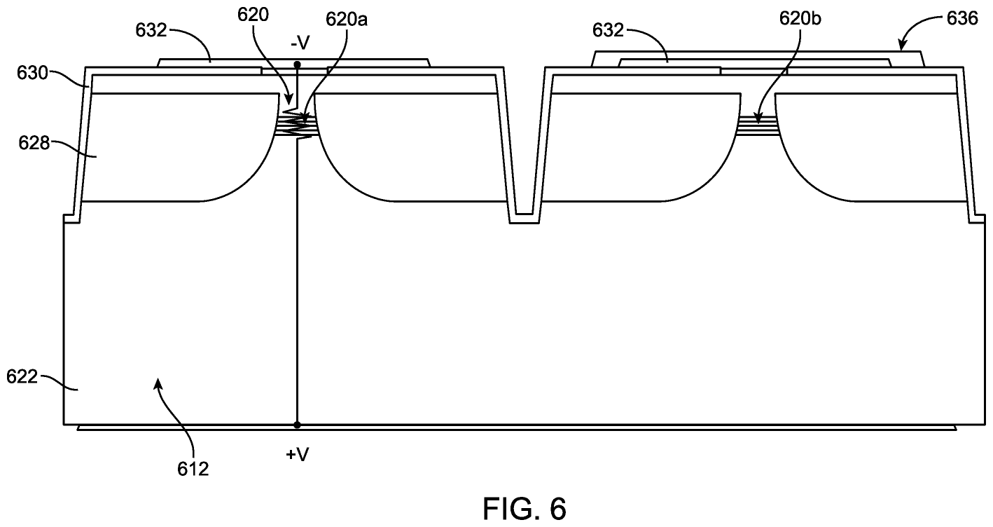

FIG. 6 is a simplified side illustration of a different, small laser array 612 that includes the substrate 622 and two lasers 620. It should be noted that that the laser array 612 will typically be designed and built to include more than two individual lasers 620 on the substrate 622, as described above. These additional lasers (not shown) can be similar to the illustrated lasers 620.

As provided herein, during the growth process, multiple layers are sequentially grown on the substrate 622, a portion of this material is removed, and filled with an insulating regrowth 628 to form the individual lasers 620.

Further, as illustrated in FIG. 6, the laser array 612 can include the insulating layer 630 that covers and separates each laser 620, and the separate electrical contact pad 632 for each of the lasers 620.

In this non-exclusive example, the two lasers 620 were tested, and the left laser 620 was determined to be a good laser 620a (e.g., sufficient optical power output), and the right laser 620 was determined to be a bad laser 620b (e.g., insufficient optical power output).

In one, non-exclusive implementation, as provided herein, each bad laser 620b can be electrically isolated with a separate, non-conducting layer 636 that is positioned in the path of at least one of the identified bad lasers 620b. In FIG. 6, the non-conducting layer 636 is an isolation dielectric cover that is positioned over the electrical contact pad 632 for the bad laser 620b. With this design, electrical isolation of the bad laser 620b is accomplished by introducing (positioning) the non-conducting layer 636 over the identified bad laser 620b. Stated in another fashion, the non-conducting layer 636 will inhibit the flow of power from the supply source 16 (illustrated in FIG. 1) through the bad laser 620b to electrically isolate the bad laser 620b, while allowing for the flow of power through the good laser 620a. In this design, electrical isolation of each bad lasers 620b can be accomplished by introducing the non-conducting layer 636 over the identified bad lasers 620b.

As a result thereof, the electrical connector assembly 514 (illustrated in FIG. 5) electrically connects the supply source 16 to the identified good lasers 620a while electrically isolating the one or more identified bad lasers 620b.

The design of the non-conducting layer 636 can vary. In a specific, non-exclusive example, the non-conducting layer 636 is a dielectric pad that is positioned (e.g., selectively deposited) over the electrical contact pad 632. As alternative, non-exclusive examples, the dielectric can be selected from a group that includes SiO2, Al2O3, Si3N4, or TiO.

As non-exclusive examples, the dielectric can be deposited with shadow mask using line of a sight deposition technique, such as evaporation or sputtering. Alternatively, the non-conducting layer 636 can be a small cap that is adhered over the electrical contact pad 632 of the identified bad laser 620b.

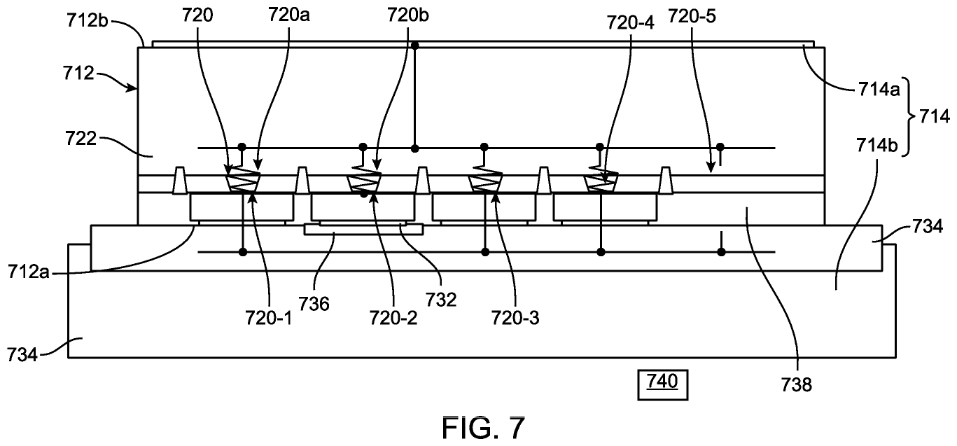

FIG. 7 is a simplified side illustration of another, different laser array 712 that includes the substrate 722 and five individual lasers 720. It should be noted that that the laser array 712 will typically be designed and built to include more than five individual lasers 720 on the substrate 722, as described above. These additional lasers (not shown) can be similar to the illustrated lasers 720.

In FIG. 7, the laser array 712 is electrically connected to the electrical connector assembly 714 with the epi side 712a down.

In this example, the laser array 712 includes five separate lasers 720, and the lasers 720 can be labeled moving left to right (i) a first laser 720-1, (ii) a second laser 720-2, (iii) a third laser 720-3, (iv) a fourth laser 720-4, and (v) a fifth laser 729-5 for convenience. As provided herein, the lasers 720 were individually tested. As an example, when tested, (i) the first, third, and fourth lasers 720-1, 720-3, 720-4 were determined to be, and are labeled as good lasers 720a; and (ii) the second and fifth lasers 720-2, 720-5 were determined to be, and are labeled as bad lasers 720b.

FIG. 7 illustrates two alternative ways to electrically isolate the bad lasers 720-2, 720-5 from the supply source 16 (illustrated in FIG. 1), while electrically connecting the good lasers 720-1, 720-3, 720-4 to the supply source 16.

More specifically, in this non-exclusive example, (i) a non-conducting layer 736 was added over the electrical pad 732 of the second laser 720-2 to electrically isolate the bad, second laser 720-2; (ii) a portion of the fifth laser 720-5 has been physically removed and filled with an electrically insulating material 738. With this design, the electrical isolation of the second laser 720-2 is accomplished by addition (e.g., the non-conducting layer 736); and the electrical isolation of the fifth laser 720-5 is accomplished by subtraction, e.g., removing a portion of the laser so it will not be bonded. For example, the removal can be accomplished with a cutting device 740 (illustrated as a box) that generates a cutting laser beam or an ion beam. Alternatively, the cutting device 740 can use chemical etching to remove at least a portion of the bad laser 720b (e.g., the fifth laser 720-5).

In the non-exclusive implementation of FIG. 7, the electrical connector assembly 714 includes (i) the first conductor plate 714a that is electrically connected to the base side 712b of the laser array 412 and each of the lasers 720, and (ii) the second conductor plate 414b that is electrically connected to the good lasers 720a via the solder 734, and electrically isolated from the bad lasers 720b. In this design, (i) the second conductor plate 414b is electrically connected (e.g., by solder) to the electrical contact pads 732 of the first, third, and fourth lasers 720-1, 720-3, 720-4; and (ii) the second conductor plate 414b is not electrically connected to the second and fifth lasers 720-2, 720-5.

Thus, in the laser array 712 illustrated in FIG. 7, (i) the first, third, and fourth lasers 720-1, 720-3, 720-4 are electrically connected to the supply source 16; and (ii) the second and fifth lasers 720-2, 720-5 are electrically isolated from the supply source 16. With this design, power from the supply source 16 (illustrated in FIG. 1) will only power the first, third, and fourth lasers 720-1, 720-3, 720-4.

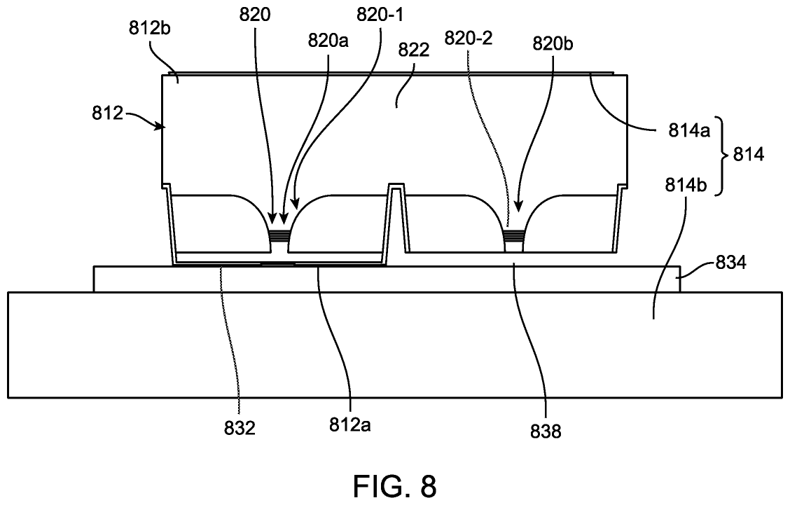

FIG. 8 is a simplified side illustration of yet another implementation of a laser array 812 that includes the substrate 822 and two individual lasers 820 with the epi side 812a down. It should be noted that that the laser array 812 will typically be designed and built to include more than two individual lasers 820 grown on the substrate 822, as described above. These additional lasers (not shown) can be similar to the illustrated lasers 820.

In the non-exclusive implementation of FIG. 8, the electrical connector assembly 814 includes the first conductor plate 814a that is electrically connected to the base side 812b of the laser array 812, and the second conductor plate 814b that is electrically connected (e.g., by solder 834) to the electrical contact pad(s) 832.

In this example, the two separate lasers 820 can be labeled moving left to right as (i) a first laser 820-1, and (ii) a second laser 820-2. Further, the two lasers 820 illustrated were tested, with the first laser 820-1 being determined to be a good laser 820a, and the second laser 820-2 being determined to be a bad laser 820b. As illustrated in FIG. 8, a portion of the second laser 820-2 has been removed, e.g., with the cutting device 740 (illustrated in FIG. 7) to create a void 838 in the second laser 820-2. This void 838 can optionally be filled with an electrically insulating material (not shown in FIG. 8).

In FIG. 8, (i) the second conductor plate 814b is electrically connected (e.g., by solder 834) to the electrical contact pad 832 of the first laser 820-1; and (ii) the second conductor plate 814b is not electrically connected to the second laser 820-2. Thus, with this design, power from the supply source 16 (illustrated in FIG. 1) will drive only the first laser 820-1.

In certain implementations, optionally, prior to removing portions of the bad laser(s) 820b, the electrical contact pads 832 of the good lasers 820a can be covered with a protective coating (not shown) to protect the good lasers 820a during the removal process. For example, the protective coating can include Parylene masking (or a photoresist layer) to protect the good lasers 820a from the ion/laser milling. Subsequently, after material has been removed from the bad lasers 820b, the protective coating can be removed. For example, the protective coating can be removed by etching with a shadow mask using a line of sight etching technique like reactive ion etching or ion milling, such that good lasers 820a are no longer electrically isolated.

Additionally, and/or optionally, the ends of the laser array 814 can also coated with the protective coating to prevent shorting on the sidewall.

In summary, as provided herein, the bad lasers are electrically isolated from the electrical connector assembly. For example, (i) one or more of the bad lasers can be electrically isolated using an addition process, e.g., the non-conducting layer; and/or (ii) one or more of the bad lasers can be electrically isolated using a subtraction process, e.g., ablation of the bad laser.

While the particular systems as shown and disclosed herein is fully capable of obtaining the objects and providing the advantages herein before stated, it is to be understood that it is merely illustrative of the presently preferred embodiments of the invention and that no limitations are intended to the details of construction or design herein shown other than as described in the appended claims.

1. A laser assembly that is powered by a supply source, the laser assembly comprising:
a substrate;
a laser array including a plurality of spaced apart, lasers grown on the substrate; wherein at least two of the lasers are individually tested to identify if the tested lasers are a good laser or a bad laser, and wherein the laser array includes an identified good laser and an identified bad laser; and
an electrical connector assembly that is adapted to electrically connect the supply source to the identified good laser while electrically isolating the identified bad laser.

2. The laser assembly of claim 1 wherein the electrical connector assembly includes a non-conducting layer that is positioned in the path of the identified bad laser.

3. The laser assembly of claim 2 wherein the identified bad laser includes an electrical pad and wherein the non-conducting layer is a dielectric that is positioned over the electrical pad.

4. The laser assembly of claim 3 wherein the non-conducting layer is selected from a group that includes silicon dioxide, aluminum oxide, silicon nitride, and titanium oxide.

5. The laser assembly of claim 3 wherein the dielectric is deposited with a shadow mask using a line of sight deposition technique.

6. The laser assembly of claim 1 wherein at least one of the lasers is a quantum cascade gain medium.

7. The laser assembly of claim 1 wherein each of the lasers is individually tested to identify if the tested lasers are a good laser or a bad laser; and wherein the laser array includes a plurality of identified good lasers; and wherein the electrical connector assembly is adapted to electrically connect the supply source to each of the identified good lasers while electrically isolating each of the identified bad lasers.

8. (canceled)

9. (canceled)

10. A laser assembly that is powered by a supply source, the laser assembly comprising:
a substrate;
a laser array including a plurality of spaced apart, lasers grown on the substrate; wherein at least two of the lasers are individually tested to identify if the tested lasers are a good laser or a bad laser; wherein the laser array includes an identified good laser and an identified bad laser; and wherein at least a portion of the identified bad laser is removed after being identified as a bad laser; and
an electrical connector assembly that is adapted to electrically connect the supply source to the identified good laser while electrically isolating the identified bad laser.

11. The laser assembly of claim 10 wherein the removal is achieved by at least one of ablation and chemical etching.

12. The laser assembly of claim 10 wherein at least one of the lasers is a quantum cascade gain medium.

13. The laser assembly of claim 10 further comprising a protective layer positioned over the identified good laser to protect the identified good laser during the removal of the portion of the identified bad laser.

14. The laser assembly of claim 10 wherein each the lasers are individually tested to identify if the tested lasers are a good laser or a bad laser; and wherein the laser array includes a plurality of identified good lasers and a plurality of identified bad lasers; and wherein at least a portion of each the identified bad lasers is removed after being identified as a bad laser.

15. (canceled)

16. The laser assembly of claim 10 wherein the electrical connector assembly includes a non-conducting layer that is positioned in the path of at least one of the identified bad lasers.

17. A method for making a laser assembly powered by a supply source comprising:
providing a substrate including a laser array grown on the substrate, the laser array having a plurality of spaced apart, lasers;
individually testing at least two of the lasers to identify if the tested lasers are a good laser or a bad laser; wherein the laser array includes an identified good laser and an identified bad laser; and
electrically connecting the supply source to the identified good laser while not electrically connecting the identified bad laser with an electrical connector assembly.

18. The method of claim 17 wherein electrically connecting includes positioning a non-conducting layer in the path of the identified bad laser.

19. The method of claim 18 wherein the identified bad laser includes an electrical pad and wherein the non-conducting layer is a dielectric that is positioned over the electrical pad after individually testing.

20. The method of claim 17 wherein providing a substrate includes at least one of the lasers being a quantum cascade gain medium.

21. The method of claim 17 wherein individually testing includes individually testing each of the lasers to identify if the tested lasers are a good laser or a bad laser; and wherein the laser array includes a plurality of identified good lasers and a plurality of identified bad lasers; and wherein electrically connecting includes electrically connecting the supply source to each of the identified good lasers while electrically isolating each of the identified bad lasers.

22-28. (canceled)

29. An assembly that is powered by a supply source, the assembly comprising:
a substrate;
an array including a plurality of spaced apart, quantum cascade gain mediums grown on the substrate; wherein at least two of the quantum cascade gain mediums are individually tested to identify if the tested quantum cascade gain mediums are a good quantum cascade gain medium or a bad quantum cascade gain medium, and wherein the array includes an identified good quantum cascade gain medium and an identified bad quantum cascade gain medium; and
an electrical connector assembly that is adapted to electrically connect the supply source to the identified good quantum cascade gain medium while electrically isolating the identified bad quantum cascade gain medium.

30. The assembly of claim 29 wherein the electrical connector assembly includes a non-conducting layer that is positioned in the path of the identified bad quantum cascade gain medium.

31. The assembly of claim 30 wherein the identified bad quantum cascade gain medium includes an electrical pad and wherein the non-conducting layer is a dielectric that is positioned over the electrical pad.

32. The assembly of claim 29 wherein each of the quantum cascade gain mediums is individually tested to identify if the tested quantum cascade gain mediums are a good quantum cascade gain medium or a bad quantum cascade gain medium; and wherein the array includes a plurality of identified good quantum cascade gain mediums; and wherein the electrical connector assembly is adapted to electrically connect the supply source to each of the identified good quantum cascade gain mediums while electrically isolating each of the identified bad quantum cascade gain mediums.
